(19) United States
(12) Patent Application Publication
(10) Pub. No.: US 2014/0060639 A1
(43) Pub. Date: Mar. 6, 2014

(54) COPPER OXIDE CORE/SHELL NANOCRYSTALS FOR USE IN PHOTOVOLTAIC CELLS

(71) Applicant: ONESUN, LLC, Sausalito, CA (US)

(72) Inventors: Eitan Chaim ZEIRA, Hollis, NH (US); Wolfgang Adam MACK, JR., San Francisco, CA (US); Molly DOYLE, Sausalito, CA (US)

(73) Assignee: ONESUN, LLC, Sausalito, CA (US)

(21) Appl. No.: 13/828,320

(22) Filed: Mar. 14, 2013

Related U.S. Application Data
(60) Provisional application No. 61/696,049, filed on Aug. 31, 2012.

(51) Int. Cl. H01L 31/032

(52) U.S. Cl. CPC H01L 31/032
USPC 136/256; 136/265

(57) ABSTRACT

The present application relates to a copper oxide nanocrystal with a cupric oxide (CuO) shell surrounding a cuprous oxide (Cu₂O) core. The copper oxide core/shell nanocrystals may be used as photo-absorbers in photovoltaic cells. The copper oxide core/shell nanocrystals form a p-type semiconductor layer that coats and fills the interstitial gaps of the n-type semiconductor mesoporous structure in a photovoltaic cell. The n-type semiconductor layer may include, for example, titanium dioxide (TiO₂) particles.

### CROSS-REFERENCE TO RELATED APPLICATIONS

This application claims the benefit of U.S. provisional patent application Ser. No. 61/696,049, filed Aug. 31, 2012, the disclosure of which is hereby incorporated by reference in its entirety.

### BACKGROUND

1. Field

The present disclosure relates generally to photovoltaic devices, and more specifically to the use of copper oxide core/shell nanocrystals in photovoltaic cells (e.g., solar cells) or other cells (e.g., silicon cells).

2. Related Art

Photovoltaic cells, such as solar cells, have been the focus of research for many years. See Dittrich et al., “Concepts of Inorganic Solid-State Nanostructured Solar Cells.” Solar Energy Materials & Solar Cells 95 (2011): 1527-1536. Current devices typically reach, at best, an average efficiency of 7%. Recently, a higher efficiency of about 10% has been achieved through the use of high mobility, low band gap, and soluble CsSnI crystals as the hole conductor/absorber. See Chung et al., “All Solid-State Dye-Sensitized Solar Cells with High Efficiency.” Nature 485 (2012). This material, however, is unstable in air.

Other materials have also been considered for use as the photovoltaic absorber. For example, previous attempts to use Cu₂O as a photovoltaic absorber have resulted in low current densities due to recombination at grain boundaries within the copper oxide layer. See Bugarinovic et al., “Solar Cells-New Aspects and Solutions; Cuprous Oxide as an Active Material for Solar Cells.” InTech, Rijeka, 2011; B. P. Rai, “Cu2O Solar Cells: A Review”, Solar Cells 25/3 (1988): 265-272; Atwater et al., “Thin, Free-Standing Cu2O Substrates via Thermal Oxidation for Photovoltaic Devices.” 38^{th} IEEE Photovoltaics Specialist Conference, IEEE (2012).

Thus, what is needed in the art is a material that can be used as an absorber in photovoltaic devices, such as solar cells, that has high mobility and high stability.

### BRIEF SUMMARY

The present disclosure addresses this need by providing copper oxide core/shell nanocrystals that have high mobility and high stability, for use as an absorber in photovoltaic devices (e.g., solar cells) and other devices (e.g., silicon cells).

In one aspect, provided is a nanocrystal that includes a core made up of cuprous oxide (Cu₂O), and a shell made up of cupric oxide (CuO). The shell may have a thickness between 2 nm and 20 nm. The nanocrystal may have a size between 5 nm and 50 nm. The ratio of the diameter of the core to the thickness of the shell may correspond to the ratio of the hole mobility of the core to the hole mobility of the shell. For example, in one embodiment, the ratio of the diameter of the core to the thickness of the shell is 10-75:0.1-5. In certain embodiments, the ratio of the diameter of the core to the thickness of the shell is between 10:0.1 and 75:0.1, between 15:0.1 and 70:0.1, between 20:0.1 and 60:0.1, between 30:0.1 and 50:0.1, between 10:1 and 75:1, between 15:1 and 70:1, between 20:1 and 60:1, between 30:1 and 50:1, or between 10:1 and 30:1, between 20:1 and 50:1, or between 40:1 and 75:1. In yet other embodiments, the ratio of the diameter of the core to the thickness of the shell is about 10:0.1, about 10:5, about 75:0.1, about 75:5, about 10:1, about 20:1, about 30:1, about 40:1, about 50:1, about 60:1, or about 70:1. The shell may completely or partially surround the core. In one embodiment, the nanocrystal may be substantially spherical. In other embodiments, the nanocrystal may exist in various other shapes and forms including, for example, rods, cubes, disks, pyramids, prisms, and ovoids.

In another aspect, provided is a device that includes a p-type semiconductor layer and a n-type semiconductor layer. The p-type semiconductor layer includes a plurality of nanocrystals, in which each nanocrystal has a core made up of Cu₂O, and a shell made up of CuO. The n-type semiconductor layer includes a plurality of particles selected from, for example, titanium dioxide particles, zinc oxide particles, zirconium oxide particles, and any combinations thereof. In one embodiment, the device may further include a metal electrode; and a hole injection layer, wherein the hole injection layer is between the metal cathode and the p-type semiconductor layer. The hole injection layer may, for example, be made up of poly(3,4-ethylenedioxythiophene) (PEDOT), carbon black, or a combination thereof. In another embodiment, the device may further include a polymeric substrate; a transparent conductor; and an electron injection layer. The transparent conductor is coated on the polymeric substrate. The electron injection layer is between the n-type semiconductor layer and the transparent conductor, and may, for example, be made up of titanium oxide. The device described herein has an average efficiency of at least 7%. In some embodiments, the device may be a photovoltaic cell.

### DESCRIPTION OF THE FIGURES

The present disclosure can be best understood by reference to the following description taken in conjunction with the accompanying figures, in which like parts may be referred to by like numerals.

FIG. 1 depicts an exemplary copper oxide core/shell nanocrystal;

FIG. 2 depicts part of an exemplary photovoltaic cell with copper oxide core/shell nanocrystals filling the interstitial spaces of a titanium dioxide mesoporous structure;

FIG. 3 depicts an exemplary interface between copper oxide core/shell nanocrystals and titanium dioxide particles;

FIG. 4 depicts the stack of layers in an exemplary photovoltaic cell; and

FIG. 5 depicts an exemplary schematic of a tandem Si cell with copper oxide core/shell nanocrystals.

### DETAILED DESCRIPTION

The following description sets forth numerous specific configurations, parameters, and the like. It should be recognized, however, that such description is not intended as a limitation on the scope of the present invention, but is instead provided as a description of exemplary embodiments.

### Copper Oxide Core/Shell Nanocrystals

Provided herein are copper oxide core/shell nanocrystals for use in photovoltaic devices, such as solar cells. These nanocrystals have a cuprous oxide (Cu2O) core, and a cupric oxide (CuO) shell that at least partially surrounds the core. This Cu2O/CuO structure benefits from the high mobility of Cu2O and the stability of CuO.

Cu2O is a non-toxic, low cost, earth abundant material with an ideal band gap and a long minority carrier diffusion length, making it a desirable absorber for solar cells. However, as discussed above, Cu2O as a photovoltaic absorber has resulted in low current densities due to recombination at grain boundaries within the copper oxide layer. The presence of a CuO layer surrounding the Cu2O material can protect high mobility cuprous oxide from reduction, but also reduces recombination and increases current density in a bilayer photo-electrochemical cell. The Cu/Cu2O interface forms a Schottky barrier that diminishes charge transport and result in low conversion efficiency solar cells. CuO on the other hand is a more stable form of copper oxide, but has low mobility and cannot be used as a hole transport layer alone.

While CuO has been observed to naturally form on the surface of Cu2O, the layer thickness of this “native” oxide is typically less than 1 nm. See e.g., Applied Surface Science 255 (2008) 2730-2734; A. Soon et al., Surface Science 601 (2007) 5809-5813. Cu2O particles with a native CuO layer on the surface do not offer the passivation and charge transfer that would be suitable for use in photovoltaic applications. Attempts to further oxidized the Cu2O typically yields a mixed phase that occurs in the bulk, which also renders such material unsuitable for use in photovoltaic applications. See A. O. Musa, T. Akomolafe and M. J. Carter, Sol. Energy Mater. Sol. Cells, vol. 51, pp. 305-316, 1998. The presence of a mixed phase Cu2O/CuO has been shown to quench the photovoltaic effect. See e.g., S. Sunkara, et al., Catal. Today (2012).

In contrast to the Cu2O materials known in the art, provided herein are Cu2O nanocrystals with a CuO shell having a thickness of between 2 nm and 20 nm. In some embodiments, the Cu2O/CuO particles typically have a size between 5 nm and 50 nm. The use of such copper oxide core/shell nanocrystals with the specific CuO shell thickness unexpectedly improves both stability and efficiency of resultant photovoltaic cells.

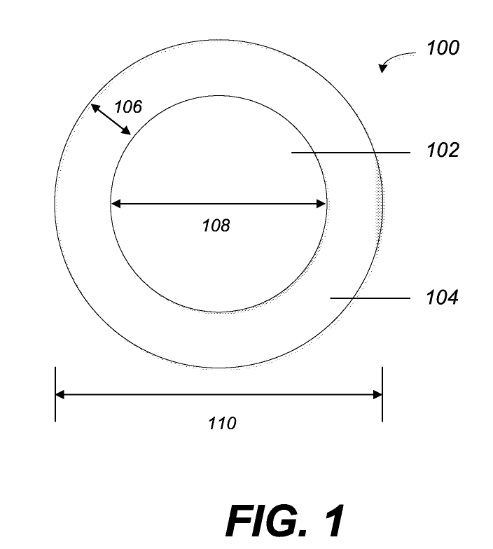

With reference to FIG. 1, exemplary nanocrystal 100 has core 102 surrounded by shell 104. A nanocrystal core surrounded by a shell is referred to as a “core/shell” nanocrystal. The term “core” refers to the inner portion of the nanocrystal. Core 102 is made up of Cu2O. The core may contain impurities. For example, a dopant can be placed within the material forming the core. The term “shell” refers to a second material that surrounds the core. Shell 104 is made up of CuO. In certain embodiments, shell 104 may further include one or more materials that are intrinsically semiconductors and stable. For example, the shell may further include nickel oxide, tungsten oxide, aluminum oxide, vanadium oxide, zirconium oxide, or any combinations thereof.

While FIG. 1 depicts shell 104 completely surrounding core 102, it should be understood that in other exemplary embodiments, the shell may partially surround the core. Thus, a shell may be “complete”, indicating that the shell completely surrounds the outer surface of the core. Alternatively, a shell may be “incomplete”, indicating that the shell partially surrounds the outer surface of the core.

The size of a nanocrystal depends on the diameter of the core and the thickness of the shell. With reference to FIG. 1, nanocrystal 100 has size 110, with core 102 having diameter 108 and shell 104 having thickness 106. For example, a spherical copper oxide nanocrystal may have an overall size of 10 nm, with a 6 nm diameter core of Cu2O surrounded by a 2 nm thick shell of CuO. In certain embodiments, the nanocrystal has a size between 5 nm and 50 nm, between 5 nm and 40 nm, between 5 nm and 30 nm, between 5 nm and 20 nm, between 5 nm and 20 nm, between 5 nm and 10 nm, between 5 nm and 7 nm, between 10 nm and 50 nm, between 10 nm and 40 nm, between 10 nm and 30 nm, between 10 nm and 20 nm, between 10 nm and 20 nm, between 15 nm and 50 nm, between 15 nm and 40 nm, between 15 nm and 30 nm, or between 15 nm and 20 nm.

Reference to “between” two values or parameters herein includes (and describes) embodiments that include the stated value or parameter per se. For example, description referring to “between x and y” includes description of “x” and “y”.

When the core has a spherical shape, as depicted in FIG. 1, the term “diameter” is as commonly understood. It should be understood, however, that the core (and hence the nanocrystal) may exist in a variety of shapes including, for example, rods, cubes, disks, pyramids, prisms, and ovoids. When the core has a non-spherical shape, the term “diameter” refers to a radius of revolution in which the entire non-spherical core would fit.

The size and shape of nanocrystals may be varied depending on the conditions (e.g., pH, temperature) used to prepare the nanocrystals. See e.g., Ke Xin Yao et al., “Synthesis, Self-Assembly, Disassembly, and Reassembly of Two Types of Cu2O Nanocrystals Unifacted with {001} or {110} Planes”, J. Am. Chem. Soc. 2010, 132, 6131-6144; Jingqu Tian et al., “One-pot green hydrothermal synthesis of CuO—Cu2O—Cu nanorod-decorated reduced grapheme oxide composites and their application in photocurrent generation”, Catal. Sci. Technol. 2012; U.S. Pat. No. 7,851,338; U.S. Pat. No. 7,825,405; U.S. Pat. No. 7,402,832.

It should be understood that the thickness of the shell may vary. In some embodiments, the shell may have a thickness of between 2 nm and 20 nm, between 3 nm and 20 nm, between 4 nm and 20 nm, between 5 nm and 20 nm, between 6 nm and 20 nm, between 7 nm and 20 nm, between 8 nm and 20 nm, between 9 nm and 20 nm, between 10 nm and 20 nm, between 11 nm and 20 nm, between 12 nm and 20 nm, between 13 nm and 20 nm, between 14 nm and 20 nm, between 15 nm and 20 nm, between 5 nm and 15 nm, or between 5 nm and 10 nm. In some embodiments, as depicted in FIG. 1, the shell may have a uniform thickness. In other embodiments, the shell may have a non-uniform thickness. For example, clumps of shell material may form on the surface of the core.

The thickness of the CuO shell may be selected to provide a balance between protecting the Cu2O core from further reduction reactions and avoiding creating too much resistance. This balance can be described by the ratio of the diameter of the core to the thickness of the shell. In some embodiments, this ratio may correspond to the ratio of the hole mobility of the core to the hole mobility of the shell. The “hole mobility” describes the speed at which electrons can move through a semiconductor material when pulled by an electric field. Hole mobility may be expressed in units of cm2/(V.s). For example, in one exemplary embodiment, if the Cu2O core has a hole mobility of 10 cm2/(V.s) and the CuO shell has a hole mobility of 1 cm2/(V.s), the ratio of the diameter of the core to the thickness of the shell is 10 to 1 (i.e., a 1 nm thick shell on a 10 nm diameter core). The ratio of the diameter of the core to the thickness of the shell may vary. In certain embodiments, the ratio of the diameter of the core to the thickness of the shell is 10-75:0.1-5. The hole mobilities of the core and the shell may vary depending on the methods in which the core and the shell are prepared. Factors that affect hole mobility may include, for example, the doping level, as well as the pH and temperature conditions at which the core and the shell are prepared.

Additionally, doping may be employed to minimize the valence band offset between the core and shell layers. Particle-to-particle charge conduction is predominantly holes as the valence band of CuO/Cu2O match, while the gap of conduction bands excludes electronic conduction. CuO typically has a valence band of 5.42 eV, whereas Cu2O has a valence band of 5.25 eV, which make particle-to-particle hole conduction feasible. The closer these valence bands are to each other, the less resistive loss will likely occur.

The copper oxide core/shell nanocrystals described herein can be synthesized by any suitable methods. For example, in one embodiment, Cu2O nanocrystals are provided or prepared, which can then be calcined at 400° C. for 1 hour in ambient conditions to form a CuO surface surrounding at least a portion of the Cu2O nanocrystal. See e.g., Z. Zhang and P. Wang. “Highly Stable Copper Oxide Composite as an Effective photocathode for Water Splitting via a Facile Electrochemical Synthesis Strategy.” Journal of Materials Chemistry 22 (2012): 2456. The resulting nanocrystal with a Cu2O core and CuO shell can then be subsequently re-grinded in a bead mill to break up agglomerates. It should be understood that other suitable methods may also employed to achieve a controlled oxidation of the Cu2O nanocrystal to form a CuO surface surrounding at least a portion of the Cu2O nanocrystal. Such methods may include, for example, the addition of controlled amounts of mild oxidants such as trimethylamino N-oxide or pyridine N-oxide.

Methods and techniques are known in the art to prepare copper oxide particles using flame spray pyrolysis. See e.g., Chiang, C-Y et al, Intl. J. of Hydrogen Energy 37 (2012) 4871-4879. In certain embodiments, copper oxide core/shell nanocrystals described herein can be produced in a two step flame spray pyrolysis process, where first reducing conditions are used to create the bulk Cu2O phase out of a liquid metal precursor spray. The growing particles are subsequently exposed to a more oxidizing condition to control the growth of the CuO phase of the outer shell. The flow rate of the central spray and the flow rate of the oxygen/methane gas can affect the thickness of the CuO shell formed. For example, to obtain a CuO shell having a thickness of between 2 nm and 20 nm, the ratio of oxygen flow rate to precursor flight rate may be between 2:1 and 3:1. Further, the total flight time of the particle can determine the overall size of the particle. For example, to obtain a nanocrystal having a size between 5 nm and 50 nm, the distance between the spray and filter that collects the particle may be between 5 cm to 1 ft.

The size, shape and distribution of the copper oxide nanocrystals may be determined by any suitable method known in the art. For example, laser scattering or a coulter counter may be used to determine particle dispersion. Atomic form microscopy may be used to determine porosity and density of particles deposited on a substrate.

### Photovoltaic Device

The copper oxide core/shall nanocrystals described herein can be used in photovoltaic devices. Such photovoltaic devices may include, for example, dye-sensitized solar cells (DSSC) or silicon cells. See e.g., B. E. Hardin, et al., “The renaissance of dye-sensitized solar cells”, Nature Photonics, Vol. 6, March 2012: 162-169; R. Motoyoshi, et al., “Fabrication and Characterization of Copper System Compound Semiconductor Solar Cells”, Adv. in Mat. Sc. and Eng., Vol. 2010, Article ID 562842 (11 pages). For example, the copper oxide core/shall nanocrystals may be used in DSSCs as a photovoltaic absorber and/or an interface layer to provide the appropriate band energy structure between the copper oxide photon absorber and the n-type semiconductor (e.g., TiO2 semiconductor).

The use of the copper oxide nanocrystals described herein increases the efficiency of a photovoltaic device. In some embodiments, the device has an average efficiency of at least 7%, at least 10%, at least 15%, at least 20%, at least 25%, at least 30%, at least 40%, or at least 50%. In some embodiments, the device has an average efficiency of between 7% and 90%, between 7% and 80%, between 10% and 50%, between 10% and 30%, or between 20% and 70%. As used herein, “efficiency” refers to the percentage of photons converted to electrons. Efficiency may be determined by measuring the level of power, which may be expressed in mW/cm2. For example, if the sun produces 100 mW/cm2 and the device produces 15 mW/cm2, the device can be described as having an efficiency of 15%.

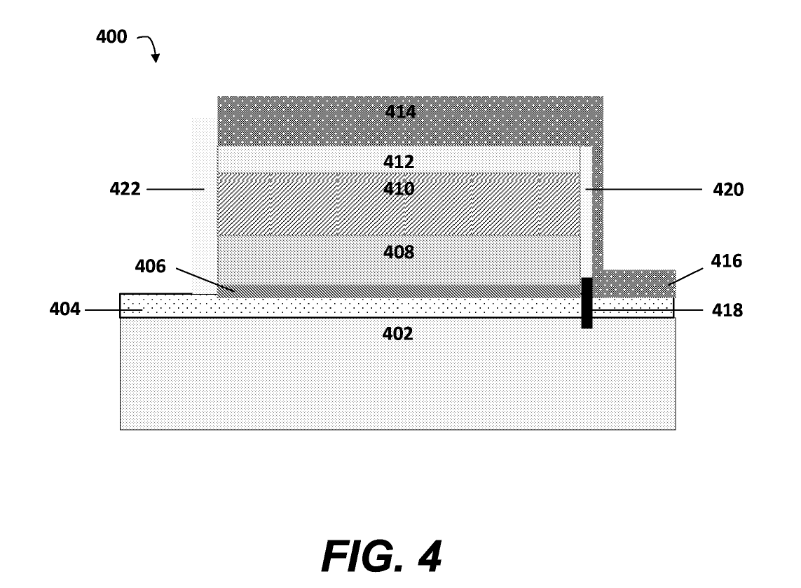

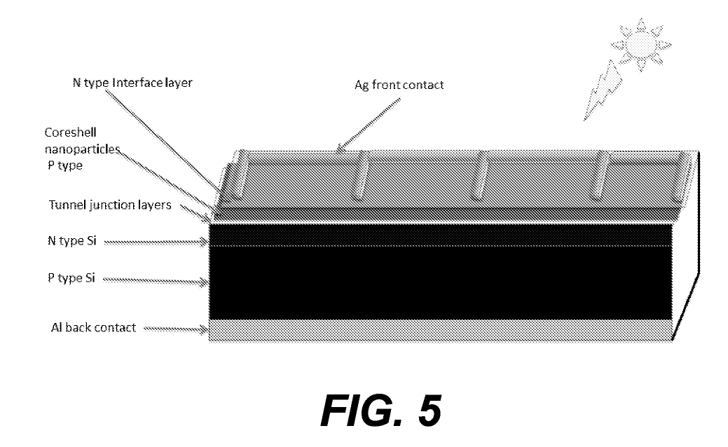

With reference to FIG. 4, exemplary photovoltaic cell 400 includes polymeric substrate 402, transparent conductor 404, electron injection layer 406, n-type semiconductor 408, p-type semiconductor 410, hole injection layer 412, and electrode 414. Each component of photovoltaic cell 400 is described in further detail below. It should be understood that, in other exemplary photovoltaic cells, certain of these components may be omitted or replaced with other suitable components, or additional components may be present in the photovoltaic cells.

a) Polymeric Substrate

Polymeric substrate 402 serves as the base for all the subsequent coated layers. In some embodiments, the polymeric substrate may have a dimensional stability of less than 1% shrinkage at 150° C.

b) Transparent Conductor

Transparent conductor 404 provides the ability for light to go through to the cell, while serving as an electrical conductor to collect the electrons generated in the cell at the anode. In some embodiments, the transparent conductor layer may have at least 85% transmission in the visible range. In other embodiments, the transparent conductor may have a sheet resistance of less than 10Ω/□.

c) Electron Injection Layer

Electron injection layer 406 (also known as an electron interface layer or a hole blocking layer) is an n-type electron transport layer that can isolate the transparent conductor from inadvertent contact with p-type semiconductor 410. In some embodiments, the electron injection layer electronically matches the conduction band energy of the n-type semiconductor with that of the transparent conductor. For example, in one embodiment, the n-type semiconductor with TiO2 particles may have a band energy of 4.2 eV, the electron injection layer with titanium oxide (TiOx) particles may have a band energy of 4.4 eV, and the transparent conductor made up of indium tin oxide (ITO) may have a band energy of 4.7 eV.

d) N-Type Semiconductor

N-type semiconductor 408 serves to grab electrons from p-type semiconductor 410, and transport the electrons to transparent conductor 404. In some embodiments, the n-type semiconductor is made up of a high band gap electron transport material with a valence band energy level that is more electronegative than the conduction band of the p-type semiconductor layer. In one embodiment, a high band gap may refer to greater than 3 eV. In another embodiment, more electronegative may refer to at least 0.3 eV. In yet other embodiments, the material making up the n-type semiconductor layer may also have electron mobility in excess of 50 cm2/(V.s).

In one embodiment, the n-type semiconductor includes a plurality of TiO2 particles. Other suitable materials may be used for the n-type semiconductor including, for example, zinc oxide particles and zirconium oxide particles. These particles typically form a mesoporous structure.

The particles making up the n-type semiconductor may have varying sizes. The particles within a given layer may be of the same size or of different sizes. The “size” of particle in the n-type semiconductor refers to the diameter of the particle. When the particle has a spherical shape, the term “diameter” is as commonly understood. The particle may, however, exist in a variety of shapes including, for example, rods, cubes, disks, pyramids, prisms, and ovoids. When the particle has a non-spherical shape, the term “diameter” refers to a radius of revolution in which the entire non-spherical particle would fit.

The plurality of particles making up the n-type semiconductor may have a distribution of sizes. For example, in one embodiment, the size of a plurality of particles may refer to the average size of the particles. For example, when the particles are TiO2 particles, in some embodiments, the particles may have a size between 100 nm and 200 nm.

e) P-Type Semiconductor

P-type semiconductor 410 serves to create electron hole pairs, donate electrons to n-type semiconductor 408 and conduct holes to electrode 414. In some embodiments, the p-type semiconductor is made up of low band gap material with high hole mobility. In one embodiment, low band gap refers to less than 2 eV. In another embodiment, high hole mobility refers to at least 25 cm2/(V.s).

In one embodiment, the n-type semiconductor includes a plurality of copper oxide nanocrystals described herein. Specifically, each nanocrystal has a core made up of Cu2O and a shell made up of CuO.

The plurality of copper oxide nanocrystals may have a distribution of sizes. For example, in one embodiment, the size of a plurality of copper oxide nanocrystals may refer to the average size of the nanocrystals. The size of the copper oxide nanocrystals in the p-type semiconductor layer may be proportional to the size of the particles in the n-type semiconductor layer. For example, in one embodiment where the n-type semiconductor layer is made up of TiO2 particles, the size of the copper oxide nanocrystals is between ⅓ and ⅕ the size of the TiO2 particles.

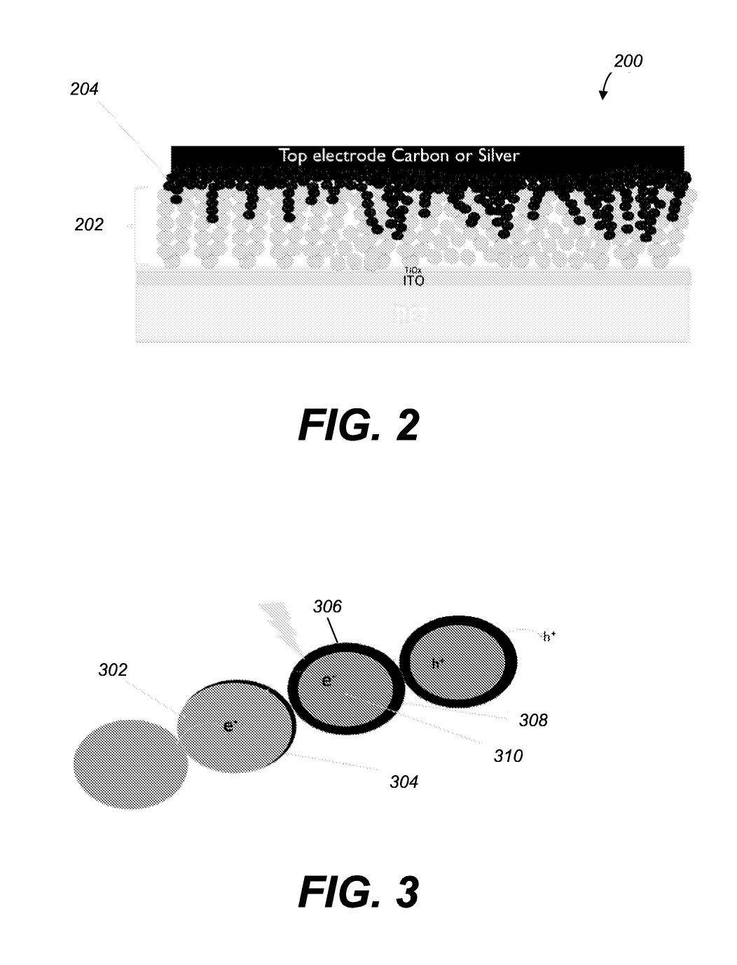

With reference to FIG. 2, in one exemplary embodiment, copper oxide nanocrystals 204 coats the top surface of TiO2 mesoporous structure 202, and fills the interstitial spaces in TiO2 mesoporous structure 202. The copper oxide nanocrystals may completely coat the top surface of the TiO2 mesoporous structure, as depicted in FIG. 2. In other embodiments, however, the copper oxide nanocrystals may partially coat the top surface of the TiO2 mesoporous structure.

The copper oxide nanocrystals may fill between 0% and 100% of the void in the n-type semiconductor. In some embodiments, the copper oxide nanocrystals fill at least 20%, at least 30%, at least 40%, at least 50%, between 20% and 100%, or between 20% and 40% of the void in the n-type semiconductor. Various techniques and methods may be employed to more fully fill the interstitial spaces in the n-type semiconductor. For example, in one embodiment, a copper (II) acetate solution may be disposed on the n-type semiconductor, followed by thermal conversion to form CuO.

Additionally, in some embodiments, an interface layer may be coated on some of the particles of the n-type semiconductor to afford better charge injection between the p-type and n-type semiconductors. With reference to FIG. 3, TiO2 particle 302 in contact with copper oxide nanocrystal 306 may be partially coated at the interface with layer 304. In some embodiments, this layer may be made up of poly(3,4-ethylenedioxythiophene) (PEDOT), carbon black, or a combination thereof.

f) Hole Injection Layer

Hole injection layer 412 (also known as a hole interface layer) serves to transfer the holes from the p-type semiconductor layer to electrode 414. The hole injection layer may be made up of a hole conductor with a high work function and a sufficiently high surface energy to enable coating the metal conductor on top of it. For example, the hole conductor has at least 5 eV. Examples of materials suitable for the hole injection layer include poly(3,4-ethylenedioxythiophene) (PEDOT), carbon black, or a combination thereof.

g) Electrode

Electrode 414 is a metal electrode or, more specifically, a cathode. The electrode may be a solid metal or metal flake ink that collects the holes. Electrode 402 may have high conductivity to conduct the holes over a long distance from cell to cell and out of the module to do work. For example, electrode 402 may have a sheet resistance of at least 1Ω/□.

h) Other Components

Photovoltaic device 400 may include other components commonly known in the art needed to make a functioning device. For example, other components may include cell-to-cell interconnect 416. Additionally, gap 418 exists between cells to enable cell-to-cell series connection. Coated insulators 420 and 422 separate cells.

### General Methods for Constructing the Photovoltaic Device

Various methods and techniques may be employed to construct a photovoltaic device, such as a photovoltaic cell, with the copper oxide core/shell nanocrystals described herein. For example, in one embodiment, an indium tin oxide (ITO) coated film (e.g., OC36 from Technimet) is first provided. Then, 0.1% titanium isopropoxide in ethanol and water is prepared, coated on top of the ITO coated film, and allowed to dry at 120° C. for 3 minutes. The resulting stack is coated by 20% solids P25 in isopropyl alcohol (IPA) and a 5 nm dispersion from Solaronix, which is then dried at 120° C. for 5 minutes. To this stack is coated a dispersion of the copper oxide cores/hell nanoparticle (as described above) in water, which is cured at 120° C. for 5 minutes, coated with PEDOT s305 diluted with ethanol, and dried at 120° C. for 5 minutes. A silver top electrode is the printed, for example using Sun chemicals SOL305 baked at 120° C. for 10 minutes.

### Other Devices

In other exemplary embodiments, the copper oxide core/shell nanocrystals described herein may be coated a top a standard silicon cell in a tandem cell-type architecture to extend the absorption spectrum of the resultant device, and therefore enhance its photovoltaic conversion efficiency. Such a tandem device, for example, would comprise a standard p/n junction silicon cell with the addition of the copper oxide core/shell nanocrystal layer coated on top, followed by the top electrode fingers or grid metal conductor that collect the charges.

For example, in one embodiment, the copper oxide core/shell nanocrystals described herein may be coated on top of a first junction, e.g., a standard silicon junction, that is mainly absorbing light in a wavelength range that is different than the wave length range absorbed by the second junction that is employing a copper oxide core/shell nanocrystal absorbing layer. By employing a recombination layer structure between the two junctions of the tandem solar cell (e.g., a tunnel junction) both Voc and Jsc can be optimized in a way that enhances the photovoltaic conversion efficiency, compared to the corresponding single-junction solar cells' performance. For instance, such a tandem solar cell may includes a standard silicon p/n junction with a thin matching tunnel diode of type Esaki diode deposited or coated on top of the silicon p/n junction. Consecutively, a p-type copper oxide core/shell layer can be coated, which may be followed by an n-type large band-gap window layer such titania or zinc oxide. Finally, the top electrode is deposited, which may consist of metal fingers or a metal grid that collect the charges.

What is claimed is:

1. A nanocrystal comprising:
a core comprising cuprous oxide (Cu₂O); and
a shell comprising cupric oxide (CuO), wherein the shell surrounds at least a portion the core, and wherein the shell has a thickness between 2 nm and 20 nm, and
wherein the nanocrystal has a size between 5 nm and 50 nm.

2. The nanocrystal of claim 1, wherein the nanocrystal has a size between 5 nm and 10 nm.

3. The nanocrystal of claim 1, wherein the core has a diameter, wherein the core and the shell each independently have a hole mobility, and wherein the ratio of the diameter of the core to the thickness of the shell corresponds to the ratio of the hole mobility of the core to the hole mobility of the shell.

4. The nanocrystal of claim 1, wherein the core has a diameter, and wherein the ratio of the diameter of the core to the thickness of the shell is 10-75:0.1-5.

5. The nanocrystal of claim 1, wherein the shell completely surrounds the core.

6. The nanocrystal of claim 1, wherein the nanocrystal is substantially spherical.

7. A device comprising:
a p-type semiconductor layer, wherein the p-type semiconductor layer comprises a plurality of nanocrystals, wherein each nanocrystal comprises a core comprising cuprous oxide (Cu₂O), and a shell comprising cupric oxide (CuO); and
a n-type semiconductor layer, wherein the n-type semiconductor layer comprises a plurality of metal oxide particles.

8. The device of claim 7, wherein the metal oxide particles are selected from the group consisting of titanium dioxide particles, zinc oxide particles, zirconium oxide particles, and any combinations thereof.

9. The device of claim 8, wherein the metal oxide particles are titanium dioxide particles.

10. The device of claim 7, further comprising:
a metal electrode; and
a hole injection layer, wherein the hole injection layer is between the metal cathode and the p-type semiconductor layer.

11. The device of claim 10, wherein the hole injection layer comprises poly(3,4-ethylenedioxythiophene) (PEDOT), carbon black, or a combination thereof.

12. The device of claim 10, further comprising:
a polymeric substrate;
a transparent conductor, wherein the transparent conductor is coated on the polymeric substrate; and
an electron injection layer, wherein the electron injection layer is between the n-type semiconductor layer and the transparent conductor.

13. The device of claim 12, wherein the electron injection layer comprises titanium oxide.

14. The device of claim 7, wherein the device has an average efficiency of at least 7%.

15. The device of claim 7, wherein the device is a photovoltaic cell.
